(19) United States
(12) Patent Application Publication
(10) Pub. No.: US 2025/0092564 A1
(43) Pub. Date: Mar. 20, 2025

(54) DEVICE AND METHOD FOR PREPARING SILICON CARBIDE CRYSTAL

(71) Applicant: TAISIC MATERIALS CORP., TAOYUAN CITY (TW)

(72) Inventors: Dai-Liang MA, TAOYUAN CITY (TW); Bang-Ying YU, TAOYUAN CITY (TW); Bo-Cheng LIN, TAOYUAN CITY (TW)

(21) Appl. No.: 18/885,756

(22) Filed: Sep. 16, 2024

Related U.S. Application Data
(60) Provisional application No. 63/583,591, filed on Sep. 19, 2023.

(30) Foreign Application Priority Data
Dec. 28, 2023 (TW) 112151418

(51) Int. Cl. C30B 23/00; C30B 23/02; C30B 29/36

(52) U.S. Cl. CPC C30B 23/005; C30B 23/02; C30B 29/36

(57) ABSTRACT

Disclosed is a device for preparing a silicon carbide crystal including a crucible and a crystal expansion guide assembly. The crucible includes a crucible body and a crucible cover fixing a seed and covering the crucible body. The crystal expansion guide assembly includes a frame member and a tubular core member. The frame member is fixed to the crucible body, located between the crucible cover and a raw material accommodated in the crucible body, and provided with a through hole with a diameter greater than a diameter of a growth surface of the seed. The tubular core member is mechanically connected to an inner wall of the through hole. During a crystal growth process, the tubular core member falls off due to contact with a growth front of a crystal. The frame member does not react with the crystal. Thus, a large-sized crystal ingot with high quality can be obtained.

### CROSS REFERENCE TO RELATED PRESENT DISCLOSURE

This application claims the priority benefit of Taiwan Patent Application Serial Number 112151418, filed on Dec. 28, 2023 and the benefit of U.S. Provisional Application No. 63/583,591, filed Sep. 19, 2023, the entire contents of which are hereby incorporated by reference herein.

### TECHNICAL FIELD

The present disclosure relates to a silicon carbide ingot preparing technique, in particular to a device for preparing a silicon carbide crystal and a method for preparing a silicon carbide crystal, which capable of preparing a crystal ingot having an edge with fewer defects.

### RELATED ART

The existing device for preparing a silicon carbide crystal usually uses a crystal expansion process to gradually obtain a larger-sized crystal. In particular, a guide component with a fixed structure (i.e., a guide component with a through hole) made of graphite material that still has a certain strength at a high temperature of more than 2300 degrees Celsius (i.e., high temperature resistance) is used. The inner diameter of the guide component is used to plan the path for the sublimation of the raw materials. During the crystal growth process using the physical vapor transport (PVT) method, the new crystal grows according to the shape of the guide component.

During the crystal expansion process of silicon carbide crystal, the edge of the crystal contact or even react with the heterogeneous materials of the guide components, causing the edge of the crystal after the crystal expansion process to connect with the graphite material. During the cooling or guide component removal process, due to the difference in thermal expansion properties of materials between the silicon carbide crystal and the guide component, tensile or compressive stress is generated on the crystal, causing the crystal to crack.

In addition, the larger the crystal grown in the crystal expansion process, the greater the internal stress. If the crystal grows at the same thickness growth rate as the original crystal of equal diameter, it is easy to break when the furnace is opened. Therefore, the general silicon carbide crystal expansion process takes longer time and has a slower growth rate than the general process of growing the crystal of equal diameter. In addition to allowing the crystal in the crystal expansion area to have sufficient kinetic energy to adjust to the growth position with the lowest activation energy during the growth process, and reducing the occurrence of defects to obtain good quality of the expanded crystal, it can also adjust the internal stress of the crystal to reduce the probability of crystal cracking after cooling.

However, when the guide component with a fixed structure is made of graphite material, the crystal prepared by the crystal preparation device is prone to produce crystal defects with polycrystalline, high carbon inclusion concentration, and polytype at the edge. The locations of defects of the crystal such as polycrystalline, high carbon inclusion concentration, and polytype are often the stress concentration areas, which cause cracks during subsequent crystal or chip processing. Therefore, when the guide component with a fixed structure is made of graphite material, it is impossible to obtain an available crystal or wafers or the availability is very low, resulting in increased material and time costs and low efficiency.

Thus, the industry has proposed a guide component with a fixed structure made of graphite material with a tantalum carbide or tungsten carbide coating (or plating) layer, which can prepare a crystal with low etching pits density (EPD). However, it has the disadvantages of high cost, brittleness, difficulty in processing, difficulty in adjusting the resistivity, difficulty in producing the N-type crystal, mismatched expansion coefficients, stress concentration, and more prominent effects when the crystal size increases. In addition, there is a problem that high-temperature metal impurities are detected in the crystal, causing failure or unexpected impact on subsequent applications.

### SUMMARY

The present disclosure provides a device for preparing a silicon carbide crystal and a method for preparing a silicon carbide crystal, which can solve the problem that the existing silicon carbide crystal preparation device uses a guide component with a fixed structure made of graphite material, which causes the inability to obtain usable ingots or wafers or the availability ratio to be very low, and the problems of high cost and the detection of high-temperature metal impurities in the crystal which causes failure or unexpected impact on subsequent applications, when the guide component with a fixed structure made of graphite material with a tantalum carbide or tungsten carbide coating (or plating) layer is used.

To solve the above technical problems, the present disclosure is implemented as follows:

The present disclosure provides a device for preparing a silicon carbide crystal, which includes a crucible and a crystal expansion guide assembly, the crucible includes a crucible body and a crucible cover, the crucible body has an internal space, the internal space is configured to accommodate a raw material, and the crucible cover is configured to fix a seed and cover the crucible body. The crystal expansion guide assembly includes a frame member and a tubular core member. The frame member is fixed to the crucible body or between the crucible body and the crucible cover, and is located between the crucible cover and the raw material (i.e., between the seed and the raw material). The frame member is provided with a through hole, and a diameter of the through hole is greater than a diameter of a growth surface of the seed. The tubular core member is flexible and is a graphite material with a purity greater than 99.9%, the tubular core member is mechanically connected to an inner wall of the through hole, am inner diameter of the tubular core member is less than or equal to the diameter of the growth surface of the seed, and a length of the tubular core member is less than a distance between a bottom end of the tubular core member and the raw material. During a crystal growth process, the tubular core member falls off to s surface of the raw material due to contact with a growth front of a crystal, and the frame member does not react with the crystal.

The present disclosure further provides a method for preparing a silicon carbide crystal, which includes the following steps: providing a system for preparing a silicon carbide crystal, which includes a device for preparing a silicon carbide crystal, a seed and a heater, wherein the device for preparing the silicon carbide crystal includes a crucible and a crystal expansion guide assembly, the crucible includes a crucible body and a crucible cover, the crucible body has an internal space, the heater is arranged around the crucible, the internal space is configured to accommodate a raw material, the crucible cover is configured to fix the seed and cover the crucible body, the crystal expansion guide assembly includes an frame member and a tubular core member, the frame member is fixed to the crucible body or between the crucible body and the crucible cover, is located between the crucible cover and the raw material (i.e., between the seed and the raw material), and is provided with a through hole, a diameter of the through hole is greater than a diameter of a growth surface of the seed, the tubular core member is flexible and is a graphite material with a purity greater than 99.9%, the tubular core member is mechanically connected to an inner wall of the through hole, an inner diameter of the tubular core member is less than or equal to the diameter of the growth surface of the seed, and a length of the tubular core member is less than a distance between the tubular core member and the raw material; and applying a growth pressure to the device for preparing the silicon carbide crystal, and applying a growth temperature to the device for preparing the silicon carbide crystal through the heater, so that a crystal grows from the seed, wherein during a crystal growth process, the frame member does not react with the crystal, and the tubular core member falls off to a surface of the raw material when a growth front of the crystal contacts the tubular core member.

In the embodiments of the present disclosure, by the design of the frame member and the tubular core member (i.e., the diameter of the through hole of the frame member is greater than the diameter of the growth surface of the seed, the tubular core member is flexible and is a graphite material with the purity greater than 99.9%, the tubular core member is mechanically connected to the inner wall of the through hole, the inner diameter of the tubular core member is less than or equal to the diameter of the growth surface of the seed, and the length of the tubular core member is less than the distance between the bottom end of the tubular core member farthest from the seed and the raw material), during the crystal growth process, the tubular core member is contacted by the growth front of the crystal and falls to the raw material, and the crystal remains non-reactive with the frame member, so that the crystal prepared by the device for preparing the silicon carbide crystal of the present disclosure has an edge with fewer defects. In addition, in the present disclosure, the frame member is only a structural component, does not participate in the reaction and can be reused, and the tubular core member of high-purity graphite material is used, and the tubular core member falls off during the crystal growth process. Compared with the guide component with a fixed structure made of graphite material with a tantalum carbide or tungsten carbide coating (or plating) layer, the crystal expansion guide assembly of the present disclosure has a lower cost and does not produce impurities that affect the subsequent process.

### BRIEF DESCRIPTION OF THE DRAWINGS

Accompanying drawings described herein are intended to provide a further understanding of the present disclosure and form a part of the present disclosure, and exemplary embodiments of the present disclosure and descriptions thereof are intended to explain the present disclosure but are not intended to unduly limit the present disclosure. In the drawings:

FIG. 1 is a structural schematic diagram of a device for preparing a silicon carbide crystal according to an embodiment of the present disclosure;

FIG. 2 is a three-dimensional schematic diagram of the crystal expansion guide assembly of FIG. 1;

FIG. 3 is a schematic diagram of the tubular core member of FIG. 1 falling off;

FIG. 4 is a structural schematic diagram of a device for preparing a silicon carbide crystal according to another embodiment of the present disclosure;

FIG. 5 is a three-dimensional schematic diagram of the crystal expansion guide assembly of FIG. 4;

FIG. 6 is a schematic diagram of the graphite material layer of FIG. 5 falling off;

FIG. 7 is a structural schematic diagram of a device for preparing a silicon carbide crystal according to still another embodiment of the present disclosure;

FIG. 8 is a three-dimensional schematic diagram of the crystal expansion guide assembly of FIG. 6;

FIG. 9 is a schematic diagram of the graphite material layer of FIG. 8 falling off;

FIG. 10 is structural schematic diagram of a system for preparing a silicon carbide crystal using the device for preparing the silicon carbide crystal of FIG. 1;

FIG. 11 is a method flow chart of an embodiment of a method preparing a silicon carbide crystal applied to the system for preparing the silicon carbide crystal of FIG. 7;

FIG. 12 is a defect diagram of an embodiment of a 6-inch wafer prepared by a guide component with a fixed structure made of graphite material in the existing device for preparing the silicon carbide crystal;

FIG. 13 is a defect diagram of a 6-inch wafer prepared by the device for preparing the silicon carbide crystal of the present disclosure;

FIG. 14 is a wafer polarization spectrum of an embodiment of an 8-inch wafer prepared by a guide component with a fixed structure made of graphite material in the existing device for preparing the silicon carbide crystal; and

FIG. 15 is a wafer polarization spectrum of an embodiment of an 8-inch wafer prepared by the device for preparing the silicon carbide crystal of the present disclosure.

### DETAILED DESCRIPTION OF THE EMBODIMENTS

The embodiments of the present disclosure will be described below in conjunction with the relevant drawings. In the figures, the same reference numbers refer to the same or similar components or method flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween.

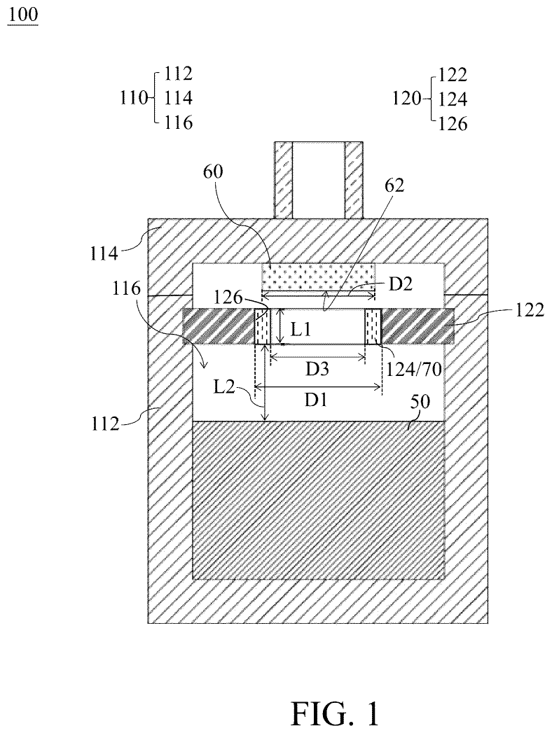

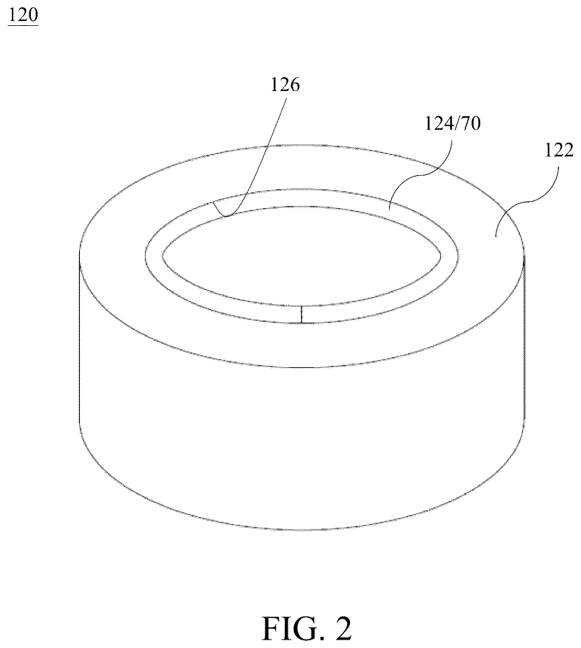

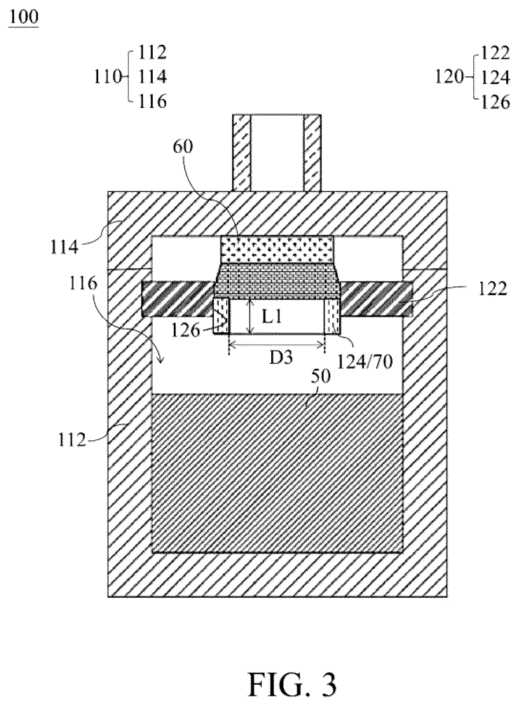

Please refer to FIG. 1 to FIG. 3. FIG. 1 is a structural schematic diagram of a device for preparing a silicon carbide crystal according to an embodiment of the present disclosure, FIG. 2 is a three-dimensional schematic diagram of the crystal expansion guide assembly of FIG. 1, and FIG. 3 is a schematic diagram of the tubular core member of FIG. 1 falling off. As shown in FIG. 1 to FIG. 3, a device for preparing a silicon carbide crystal 100 comprises a crucible 110 and a crystal expansion guide assembly 120.

The crucible 110 comprises a crucible body 112 and a crucible cover 114. The crucible body 112 has an internal space 116. The internal space 116 is configured to accommodate a raw material 50. The crucible cover 114 is configured to fix a seed 60 and cover the crucible body 112. The crucible 110 is configured to make a crystal grow on the seed 60 through the raw material 50. The crucible cover 114 may be provided with a holder (not shown), and the holder may be used to fix the seed 60 and to limit a diameter D2 of a growth surface 62 of the seed 60 (i.e., to limit the diameter D2 of the growth surface 62 exposed). The crucible 110 may be, but not limited to, a graphite crucible. The seed 60 may be made of, but is not limited to, silicon carbide. The diameter of the seed 60 may be, but not limited to, more than 6 inches (150 millimeters), and the raw material 50 may comprise, but not limited to, silicon and/or silicon carbide, and carbon. The raw material 50 may be in a form of, but not limited to, powder, granules, or blocks. The purity of the raw material 50 may be greater than 99.99%, and the crystal phase of the raw material 50 may be, but not limited to, α phase or β phase. This embodiment is not intended to limit the present disclosure.

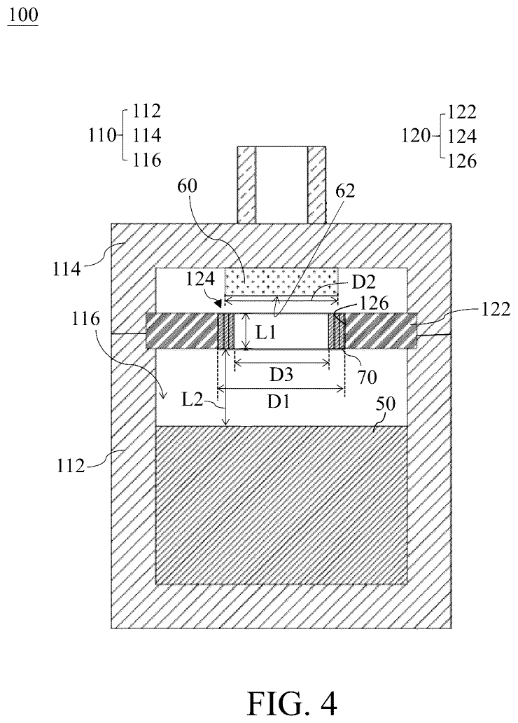

The crystal expansion guide assembly 120 comprises a frame member 122 and a tubular core member 124. The frame member 122 is fixed to the crucible body 112, and is located between the crucible cover 114 and the raw material 50 (i.e., between the seed 60 and the raw material 50). The frame member 122 may be embedded in the crucible body 112. In another embodiment, the crucible body 112 and the crucible cover 114 may be provided with stepped edges respectively, so that the frame member 122 may be sandwiched between the bottoms of the stepped edges of the crucible body 112 and the crucible cover 114 (i.e., the frame member 122 is fixed between the crucible body 112 and the crucible cover 114, as shown in FIG. 4, which is a structural schematic diagram of a device for preparing a silicon carbide crystal according to another embodiment of the present disclosure).

The frame member 122 is provided with a through hole 126. A diameter D1 of the through hole 126 is greater than the diameter D2 of the growth surface 62 of the seed 60. Therefore, the crystal maintains no reaction with the frame member 122 during the growth process. The frame member 122 is only used as a structural member, so it can be reused. The material of the frame member 122 may be, but not limited to, graphite, metal carbide or a refractory compound, the purity of the graphite, high-temperature metal carbide or refractory compound can be greater than 99.9%; the high-temperature metal carbide may be, but are not limited to, tungsten carbide, tantalum carbide, niobium carbide or titanium carbide, and has the characteristics of high temperature resistance (e.g., above 2500 degrees Celsius) and corrosion resistance. In addition, during the crystal growth process, the frame member 122 is basically not in contact with the crystal, and is only a structural component that does not participate in the reaction and can be reused.

The inner diameter D3 of the tubular core member 124 is less than or equal to the diameter D2 of the growth surface 62 of the seed 60, so that the raw material 50 can be sublimated and vaporized after being heated and deposited on the growth surface 62 of the seed 60 in the form of gas phase molecules through the tubular core member 124 (that is, the tubular core member 124 is located on the path of crystal growth and expansion). The tubular core member 124 is flexible and is made of graphite material with a purity greater than 99.9%. The tubular core member 124 is mechanically connected to the inner wall of the through hole 126, so that during the crystal growth process, the tubular core member 124 is dropped due to the contact of the growth front of the crystal (as shown in FIG. 3). The length L1 of the tubular core member 124 (i.e., the distance between the top end of the tubular core member 124 toward the seed 60 and the bottom end of the tubular core member 124 away from the seed 60) is less than the distance L2 between the tubular core member 124 and the raw material 50 (i.e., the distance between the bottom end of the tubular core member 124 away from the seed 60 and the surface of the raw material 50), so that the tubular core member 124 can eventually fall to the surface of the raw material 50 without affecting the expansion growth of the crystal, and the crystal expansion guide assembly 120 exposes a larger growth diameter of the crystal, eliminating defects and stress that may be caused by the crystal expansion growth contacting the frame member 122. In addition, by setting up the crystal expansion guide assembly 120, the internal stress of crystal can be improved, and a crystal boule with a thickness greater than 10 millimeters can be prepared, and the crystal boule does not break when the crystal boule is withdrawn from a furnace (if the internal stress of silicon carbide crystal is too large during the crystal growth process, it is impossible to grow a crystal boule with a thickness greater than 10 millimeters). It should be noted that, since the bottom end of the tubular core member 124 away from the seed 60 is arranged parallel to the bottom end of the frame member 122 away from the seed 60, the distance L2 between the tubular core member 124 and the raw material 50 is equal to the distance between the frame member 122 and the raw material 50, but this embodiment is not intended to limit the present disclosure.

In one embodiment, the outer diameter of the tubular core member 124 may be substantially equal to the diameter D1 of the through hole 126, and the tubular core member 124 may be cooperatively connected to the inner wall of the through hole 126. For example, the tubular core member 124 can be cooperatively connected to the inner wall of the through hole 126 by transition fitting due to its flexibility, so that the tubular core member 124 slides and falls to the surface of the raw material 50 due to the contact thrust when the growth front of the crystal contacts the tubular core member 124.

In one embodiment, the diameter D1 of the through hole 126 is substantially equal to a maximum growth diameter. Specifically, since the tubular core member 124 can eventually fall to the surface of the raw material 50, the space formed between the growth front of the crystal and the frame member 122 serves as a crystal expansion zone for crystal growth. Therefore, the diameter D1 of the through hole 126 is substantially equal to the maximum growth diameter.

In one embodiment, the tubular core member 124 may be formed by rolling a graphite material layer 70 with flexibility into a tubular shape, and the graphite material layer 70 may be cooperatively connected to the inner wall of the through hole 126 (as shown in FIG. 1 to FIG. 3). The graphite material layer 70 may be, but is not limited to, graphite paper, graphite foil or a graphite blanket, which has the advantage of being easy to construct into the desired shape. The thickness of the graphite material layer 70 may be, but is not limited to, 3 millimeters. After the graphite material layer 70 falls onto the raw material 50, a carbon inclusion channel can be formed on the surface of the raw material 50 to block the inner wall of the crucible 110 from the crystal, and the concentration of carbon inclusions in the crystal can be reduced, thereby reducing the causes of crystal defects (e.g., microtubes and dislocations).

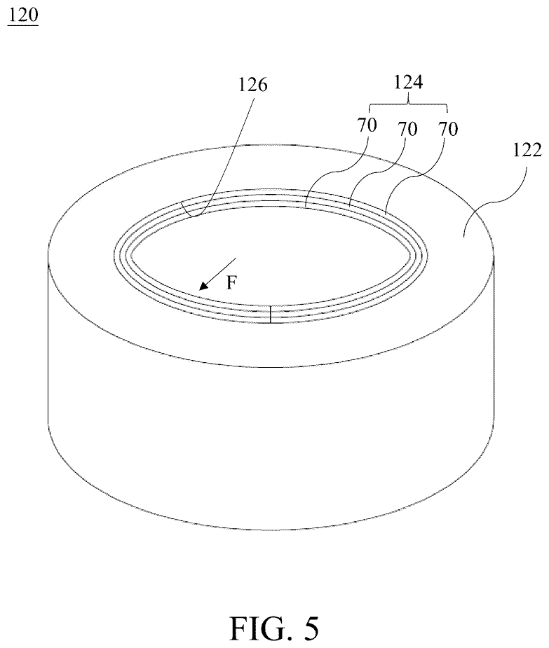

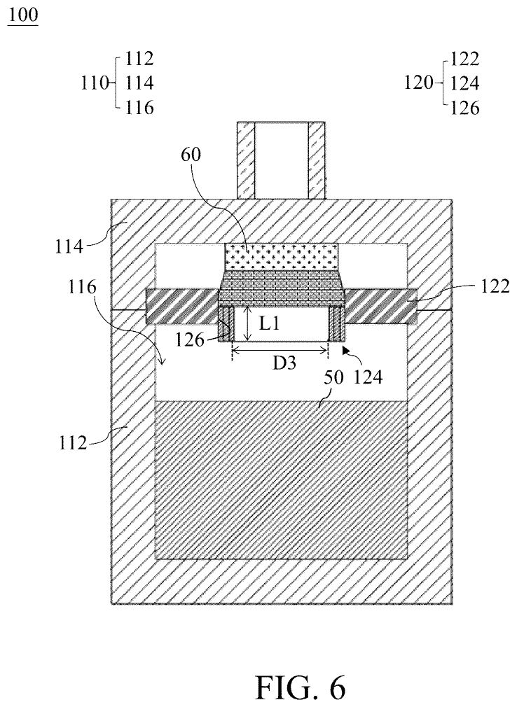

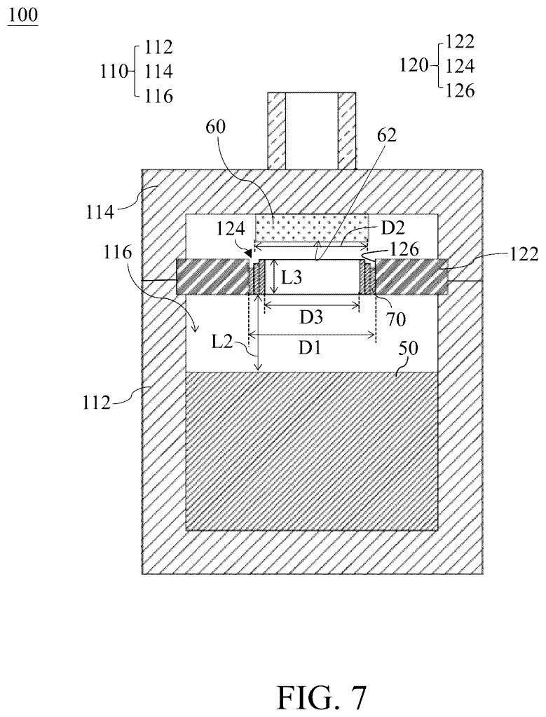

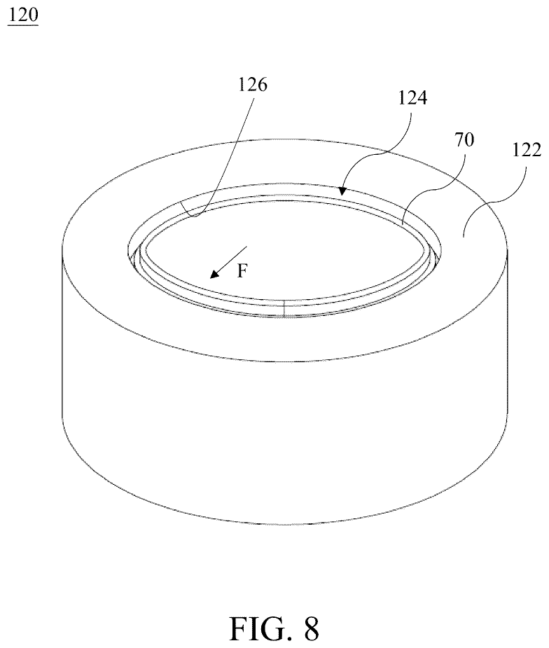

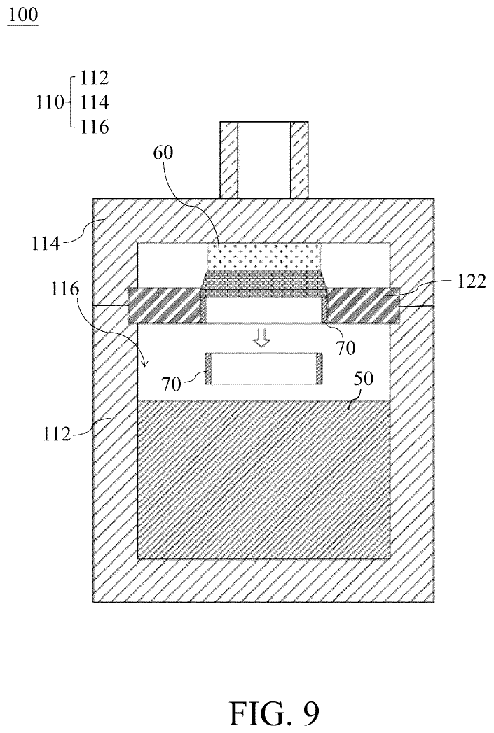

In one embodiment, the tubular core member 124 may be formed by a plurality of graphite material layers 70 with flexibility stacked together and rolled into a tubular shape, and the top ends of the plurality of graphite material layers 70 toward the seed 60 are distributed parallel along a thickness direction F of the tubular core member 124 (i.e., the direction from the inner aperture to the outer aperture of the tubular core member 124) (i.e., each graphite material layer 70 has the same length, as shown in FIG. 4 to FIG. 6, wherein FIG. 5 is a three-dimensional schematic diagram of the crystal expansion guide assembly of FIG. 4, and FIG. 6 is a schematic diagram of the graphite material layer of FIG. 5 falling off) or distributed in a descending step-like manner along the thickness direction F of the tubular core member 124 (as shown in FIG. 7 to FIG. 9, wherein FIG. 7 is a structural schematic diagram of a device for preparing a silicon carbide crystal according to still another embodiment of the present disclosure, FIG. 8 is a three-dimensional schematic diagram of the crystal expansion guide assembly of FIG. 6, and FIG. 9 is a schematic diagram of the graphite material layer of FIG. 8 falling off), and the thicknesses of the plurality of graphite material layers 70 may be the same or different. The thickness of each graphite material layer 70 may be, but is not limited to, 1 millimeter, the number of graphite material layers 70 may be, but is not limited to, three, and the number of graphite material layers 70 can be adjusted as needed.

As shown in FIG. 4 to FIG. 6, when the top ends of the graphite material layers 70 toward the seed 60 are distributed in parallel along the thickness direction F of the tubular core member 124, during the crystal growth process, the growth front of the crystal can simultaneously touch the graphite material layers 70, so that the graphite material layers 70 can simultaneously fall off to the surface of the raw material 50. Specifically, by designing the graphite material layers 70 to be stacked in parallel, when the growth front of the crystal touches the graphite material layers 70, the graphite material layers 70 can simultaneously fall off to the surface of the raw material 50.

As shown in FIG. 7 to FIG. 9, when the top ends of the graphite material layers 70 toward the seed 60 are distributed in a descending step-like manner along the thickness direction F of the tubular core member 124, during the crystal growth process, the growth front of the crystal sequentially contacts with the graphite material layers 70, so that the graphite material layers 70 that are contacted fall off to the surface of the raw material 50 in sequence. In FIG. 9, since the graphite material layers 70 are distributed in a descending step-like manner (i.e., there is a height difference between the graphite material layers 70), the second layer of the graphite material layers 70 is touched by the growth front of the crystal and falls off, and then the outermost layer of the graphite material layers 70 is touched by the growth front of the crystal and falls off. Each graphite material layer 70 may be, but is not limited to, graphite paper, graphite foil or a graphite blanket, which has the advantage of being easily constructed into a desired shape. The maximum length L3 of the three graphite material layers 70 (i.e., the length L3 of the innermost layer of the graphite material layers 70) is less than a distance L2 between the bottom end of the tubular core member 124 away from the seed 60 and the surface of the raw material 50, so that the tubular core member 124 can eventually fall to the surface of the raw material 50 without affecting the expansion growth of the crystal. It should be noted that, in this embodiment, the bottom end of the tubular core member 124 away from the seed 60 and the bottom end of the frame member 122 away from the seed 60 are arranged in parallel, so the distance L2 between the tubular core member 124 and the raw material 50 is equal to a distance between the frame member 122 and the raw material 50, but this embodiment is not intended to limit the present disclosure. In addition, after each graphite material layer 70 falls onto the raw material 50, a carbon inclusion channel can be formed on the surface of the raw material 50 to block the inner wall of the crucible 110 from the crystal, and the concentration of carbon inclusions in the crystal can also be reduced, thereby reducing the causes of crystal defects (e.g., microtubes and dislocations).

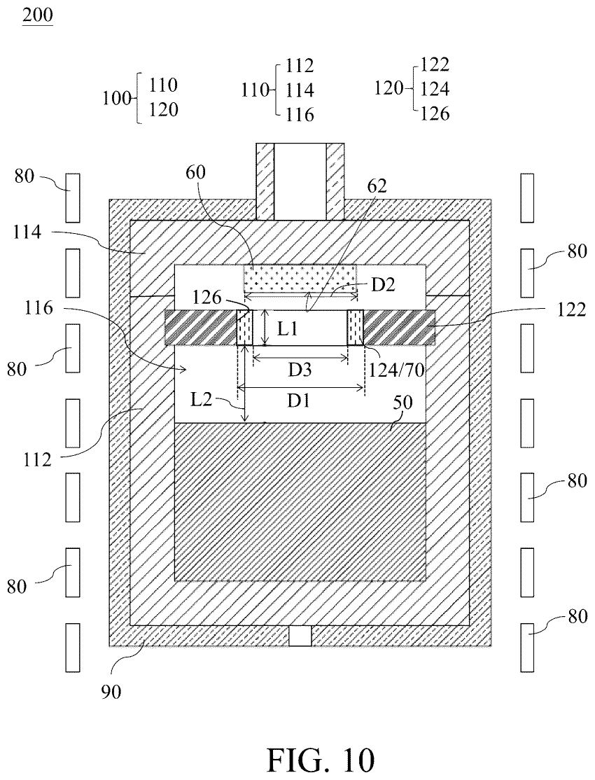

Please refer to FIG. 10, which is structural schematic diagram of a system for preparing a silicon carbide crystal using the device for preparing the silicon carbide crystal of FIG. 1. A system for preparing a silicon carbide crystal 200 comprises a device for preparing a silicon carbide crystal 100, a seed 60, and heaters 80. The heaters 80 are configured to provide a heat source. The heaters 80 are arranged around the crucible 110. The figure shows the plurality of heaters 80. In other embodiments, one heater 80 may be provided depending on the system configuration. The number of heaters 80 in the figure is for illustration only, and it does not limit the actual number of heaters 80. The heater 80 may be a high frequency heater or a resistive heater. In a more specific embodiment, the heater 80 may be a heating coil or a heating resistance wire (net). In addition, the system for preparing the silicon carbide crystal 200 may further comprise a thermal insulation material 90, which may be disposed outside the crucible body 112 and the crucible cover 114. The thermal insulation material 90 may be, but is not limited to, a porous heat-insulating carbon material to achieve the effect of temperature maintenance. In addition, the system for preparing the silicon carbide crystal 200 may use the device for preparing the silicon carbide crystal 100 of FIG. 4 or FIG. 7.

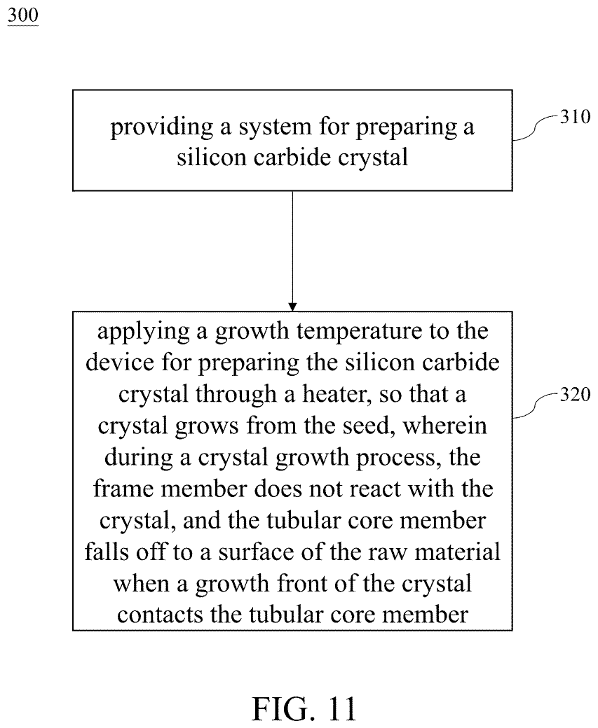

Please refer to FIG. 11, which is a method flow chart of an embodiment of a method preparing a silicon carbide crystal applied to the system for preparing the silicon carbide crystal of FIG. 7. As shown in FIG. 11, a method preparing a silicon carbide crystal 300 comprises the following steps: providing a system for preparing a silicon carbide crystal 200 (step 310); and applying a growth pressure to the device for preparing the silicon carbide crystal 100, and applying a growth temperature to the device for preparing the silicon carbide crystal 100 through a heater 80, so that a crystal grows from the seed 60, wherein during a crystal growth process, the frame member 122 does not react with the crystal, and the tubular core member 124 falls off to a surface of the raw material 50 when a growth front of the crystal contacts the tubular core member 124 (step 320). The growth pressure and the growth temperature can be adjusted according to actual needs. For example, the growth pressure may be, but is not limited to, 200 Pascals (Pa) to 500 Pa or 400 Pa to 1100 Pa. The growth temperature may comprise a temperature gradient, and the temperature gradient may comprise a temperature of an upper area of the crucible 110 and a temperature of a lower area of the crucible 110. The temperature of the lower area of the crucible 110 needs to be higher than the temperature of the upper area of the crucible 110 to form the temperature gradient, thereby generating a driving force for crystal growth, wherein the temperature of the upper area of the crucible 110 may be, but is not limited to, 1950° C. to 2150° C. or 2100° C. to 2200° C., and the temperature of the lower area of the crucible 110 is higher than the temperature of the upper area of the crucible 110. The temperature of the upper area of the crucible 110 and the temperature of the lower area of the crucible 110 may be adjusted according to actual needs.

In one embodiment, step 320 may further comprise: using a space formed between the growth front of the crystal and the frame member 122 as a crystal expansion zone after the tubular core member 124 falls off to the surface of the raw material 50, so that the crystal grows in the crystal expansion zone. When the crystal grows in the crystal expansion zone, the crystal is not blocked by the frame member 122 and does not react with the frame member 122. Therefore, the crystal prepared by the method preparing the silicon carbide crystal 300 can have a low-defect, low-stress edge. The stress at the edge of the crystal produces a low angle grain boundary (LAGB), there is a stress concentration point at the tip of the LAGB, which is easy to cause the crystal boule to break when the crystal boule is withdrawn from a furnace and the crystal to break during processing. After the edge stress of the crystal is improved, the first pass yield of crystal processing from ingot to wafer (chip) can be improved and the production cost can be reduced.

When the system for preparing the silicon carbide crystal 200 can use the device for preparing the silicon carbide crystal 100 of FIG. 1 (that is, the tubular core member 124 can be formed by a graphite material layer 70 with flexibility rolled into a tubular shape, and the graphite material layer 70 is cooperatively connected to the inner wall of the through hole 126) or use the device for preparing the silicon carbide crystal 100 of FIG. 4 (that is, the tubular core member 124 can be formed by a plurality of graphite material layers 70 with flexibility rolled into a tubular shape, and the graphite material layers 70 are stacked in parallel and are cooperatively connected to the inner wall of the through hole 126), step 320 may comprise: during the crystal growth process, the graphite material layer 70/the plurality of graphite material layers 70 falling off from the frame member 122 to the surface of the raw material 50 when the growth front of the crystal contacts the graphite material layer 70/the plurality of graphite material layers 70.

In addition, step 320 may further comprise: preventing, by the graphite material layer(s) 70 that has/have not fallen off, free carbon generated by the frame member 122 when heated from entering the crystal (that is, the tubular core member 124 prevents the free carbon generated by the frame member 122 when heated from entering the crystal in the early stage of crystal growth). Specifically, the free carbon generated by the frame member 122 after being heated affects the growth of the two-dimensional seed of silicon carbide. Therefore, the setting of the graphite material layer(s) 70 that has/have not fallen off can avoid this situation.

Besides, the existing guide component with the fixed structure made of graphite material inevitably introduces impurities (e.g., aluminum, nitrogen, and boron) into the growth atmosphere after being heated, causing heterogeneous nucleation at the growth interface in the initial stage of growth, thereby preventing the two-dimensional seed growth of silicon carbide and forming polymorphic inclusions, and significantly destroying the stability of the thermal field and flow field at the front of the growth interface. Therefore, the setting of the frame member 122 that does not participate in the reaction and the high-purity graphite material layer 70 that falls off only when touched in the present disclosure can avoid the occurrence of the above situation.

When the system for preparing the silicon carbide crystal 200 can use the device for preparing the silicon carbide crystal 100 of FIG. 7 (that is, the tubular core member 124 is formed by a plurality of graphite material layers 70 with flexibility rolled into a tubular shape, and the top ends of the graphite material layers 70 toward the seed 60 are distributed in a descending step-like manner along the thickness direction F of the tubular core member 124 and are stacked and cooperatively connected to the inner wall of the through hole 126), step 320 may comprise: during the crystal growth process, the plurality of graphite material layers 70 that are contacted falling off to the surface of the raw material 50 in sequence when the growth front of the crystal sequentially contacts the plurality of graphite material layers 70. In addition, step 320 may further comprise: preventing, by the graphite material layer(s) 70 that has/have not fallen off, free carbon generated by the frame member 122 when heated from entering the crystal.

In one embodiment, the crystal may be selected from the group consisting of 4H silicon carbide, 6H silicon carbide, and 15R silicon carbide, but this embodiment is not intended to limit the present disclosure. For example, the crystal may be other polytypes of silicon carbide.

In one embodiment, the crystal may comprise semi-insulating silicon carbide.

In one embodiment, the crystal may comprise n-type silicon carbide.

In one embodiment, the crystal may comprise p-type silicon carbide.

In one embodiment, the diameter of the seed 60 may be, but is not limited to, more than 6 inches, and the diameter of the crystal after expansion growth using the method for preparing the silicon carbide crystal 300 may be, but not limited to, 145 millimeters to 205 millimeters. It should be noted that when the holder fixes the seed 60, the diameter D2 of the exposed growth surface 62 is limited (the diameter D2 of the exposed growth surface 62 is less than the diameter of the seed 60). Therefore, the diameter of the crystal after expansion growth may be less than the diameter of the seed 60. The diameter of the crystal after expansion growth can be determined according to the diameter D1 of the through hole 126 of the frame member 122.

In one embodiment, the crystal after expansion growth can be a silicon carbide single crystal ingot with a convex or flat surface.

Please refer to Table 1, which is a relationship table of the diameter of the through hole of the frame member, the number of graphite material layers of the tubular core member, the diameter of the growth surface of the seed (i.e., the diameter of the growth surface of the seed exposed when the holder fixes the seed), the expansion diameter, the growth pressure and the growth temperature in different embodiments, wherein the thickness of each graphite material layer can be 1 millimeter, and the final crystal diameter (i.e., the maximum growth diameter) can be substantially equal to the diameter of the through hole of the frame member, the expansion diameter is the difference between the final crystal diameter and the diameter of the growth surface of the seed, the growth temperature may include a temperature of an upper area of the crucible and a temperature of a lower area of the crucible, the temperature of the lower area of the crucible is higher than the temperature of the upper area of the crucible, and the thickness of the frame member (i.e., the distance between the top end of the frame member toward the seed and the bottom end of the frame member away from the seed) can be but not limited to 30 millimeters.

TABLE 1

| | Diameter of | | Diameter of | | | Temperature |
|---|---|---|---|---|---|---|
| | the through | Number of | the growth | | | of an upper |
| | hole of the | graphite | surface of | Expansion | Growth | area of the |
| | frame member | material | the seed | diameter | pressure | crucible |
| | (mm) | layers | (mm) | (mm) | (pa) | (° C.) |
| Embodiment 1 | 149 | 2 | 145 | 4 | 400-1100 | 2100-2200 |
| Embodiment 2 | 151 | 3 | 145 | 6 | 400-1100 | 2100-2200 |
| Embodiment 3 | 155 | 5 | 145 | 10 | 400-1100 | 2100-2200 |
| Embodiment 4 | 203 | 5 | 193 | 10 | 200-500 | 1950-2150 |

As can be seen from Table 1, the appropriate growth pressure and the appropriate growth temperature are applied to the device for preparing the silicon carbide crystal, so that the crystal grows from the seed; the final crystal diameter (i.e., the maximum growth diameter) can be limited by the diameter of the through hole of the frame member; the number of graphite material layers can be adjusted according to actual needs (e.g., the diameter of the through hole of different frame members).

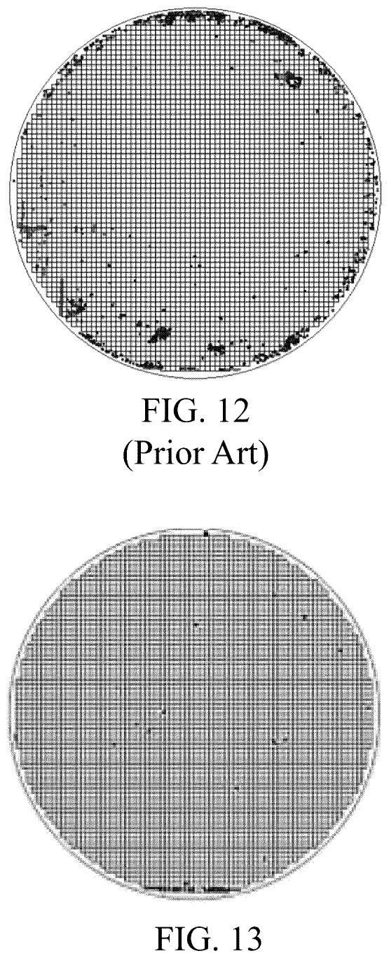

Please refer to FIG. 12 and FIG. 13. FIG. 12 is a defect diagram of an embodiment of a 6-inch wafer prepared by a guide component with a fixed structure made of graphite material in the existing device for preparing the silicon carbide crystal, and FIG. 13 is a defect diagram of a 6-inch wafer prepared by the device for preparing the silicon carbide crystal of the present disclosure. The existing device for preparing the silicon carbide crystal uses a diameter of the growth surface of the seed of 145 millimeters, a diameter of the through hole of a guide component with a fixed structure of 152 millimeters, a growth pressure of 400 Pa and a temperature of an upper area of the crucible of 2120° C. to generate a crystal with a final crystal diameter of 153 millimeters; next, the crystal is processed into an ingot with a diameter of 150 millimeters; and then the ingot is cut and polished to prepare a wafer with a diameter of 150 millimeters; finally the wafer surface defect detection is performed on the wafer after a surface cleaning process to obtain the defect diagram of FIG. 12. The device for preparing the silicon carbide crystal of the present disclosure uses a diameter of the growth surface of the seed of 145 millimeters, a diameter of the through hole of the frame member of 155 millimeters, the tubular core member of five graphite material layers (the thickness of each graphite material layer can be 1 millimeter), a growth pressure of 400 Pa and a temperature of an upper area of the crucible of 2125° C. to generate a crystal with a final crystal diameter of 154.5 millimeters; next, the crystal is processed into an ingot with a diameter of 150 millimeters; and then the ingot is cut and polished to prepare a wafer with a diameter of 150 millimeters; finally the wafer surface defect detection is performed on the wafer after a surface cleaning process to obtain the defect diagram of FIG. 13.

The black dots in FIG. 12 and FIG. 13 are defects of the wafers. In FIG. 12, the total number of defects in the wafer is 1279, the total defect density (TDD) of the wafer is about 7.89/cm\hat{ }2, the number of micropipes is 606, the micropipe density (MPD) is about 3.74/cm\hat{ }2, and most of the defects are distributed at the edge of the wafer. In FIG. 13, the total number of defects in the wafer is 41 (some defects at the laser engraving of the large flat edge may be misjudged by the inspection machine, and the actual total number of defects is even smaller), the total defect density of the wafer is about 0.25/cm\hat{ }2, the number of micropipes is 3, the micropipe density is about 0.02/cm\hat{ }2, and the edge is clean with few defects. Therefore, it can be seen from FIG. 12 and FIG. 13 that the wafer prepared by the device for preparing the silicon carbide crystal of the present disclosure has the low-defect and low-stress edge compared to the wafer prepared by the existing device for preparing the silicon carbide crystal, and the overall defect density caused by the impurities of the crystal expansion guide assembly or the silicon vapor erosion of the wall and the carbon inclusions generated by the crystal expansion guide assembly in the wafer obtained by using the device for preparing the silicon carbide crystal of the present disclosure is greatly reduced.

The ingots with the diameter of 150 millimeters (i.e., 6 inches) processed in the embodiments of FIG. 12 and FIG. 13 are all made into 12 silicon carbide wafers with the diameter of 6 inches. Among the 12 wafers obtained in the embodiment of FIG. 12, 5 wafers are broken during processing, and 7 wafers are finally processed. Among the 7 wafers, only one wafer has an MPD less than 1/cm\hat{ }2, which meets the commercial product specifications, and the wafer yield is 8.3%. Among the 12 wafers obtained in the embodiment of FIG. 13, 12 wafers are finally processed (no cracking during processing), and the MPD of each of all 12 wafers is less than 1/cm\hat{ }2, and the yield of product-level wafers is 100%. Therefore, it can be seen that by improving the edge stress of the crystal and the crystal defects caused by the stress, the overall crystal defect density is reduced, and the yield of product-level wafers is improved.

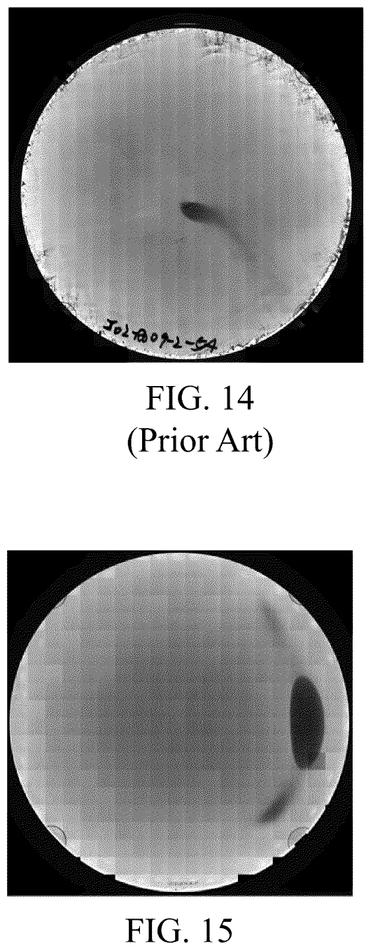

Please refer to FIG. 14 and FIG. 15. FIG. 14 is a wafer polarization spectrum of an embodiment of an 8-inch wafer prepared by a guide component with a fixed structure made of graphite material in the existing device for preparing the silicon carbide crystal, and FIG. 15 is a wafer polarization spectrum of an embodiment of an 8-inch wafer prepared by the device for preparing the silicon carbide crystal of the present disclosure. The existing device for preparing the silicon carbide crystal uses a diameter of the growth surface of the seed of 193 millimeters, a diameter of the inner hole of a guide component with a fixed structure of 200 millimeters, a growth pressure of 200 Pa and a temperature of an upper area of the crucible of 1980° C. to prepare a crystal with a final crystal diameter of 203 millimeters; next, the crystal is cut and polished to prepare a wafer with a diameter of 200 millimeters of FIG. 14. The device for preparing the silicon carbide crystal of the present disclosure uses a diameter of the growth surface of the seed of 195 millimeters, a diameter of the through hole of the frame member of 205 millimeters, the tubular core member of five graphite material layers (the thickness of each graphite material layer can be 1 millimeter), a growth pressure of 200 Pa and a temperature of an upper area of the crucible of 2000° C. to prepare a crystal with a final crystal diameter of 203-204 millimeters; next, the crystal is cut and polished to prepare a wafer with a diameter of 200 millimeters of FIG. 15. As shown in FIG. 14 and FIG. 15, the wafer prepared by the device for preparing the silicon carbide crystal of the present disclosure has a low-defect and low-stress edge compared to the wafer prepared by the existing device for preparing the silicon carbide crystal, and the defects of polycrystalline insertions caused by impurities in the crystal expansion guide assembly or silicon vapor erosion of the wall and carbon inclusions generated by the crystal expansion guide assembly in the wafer obtained by using the device for preparing the silicon carbide crystal of the present disclosure are reduced.

In summary, by the design of the frame member and the tubular core member (i.e., the diameter of the through hole of the frame member is greater than the diameter of the growth surface of the seed, the tubular core member is flexible and is a graphite material with a purity greater than 99.9%, the tubular core member is mechanically connected to the inner wall of the through hole, the inner diameter of the tubular core member is less than or equal to the diameter of the growth surface of the seed, and the length of the tubular core member is less than the distance between the bottom end of the tubular core member away from the seed and the raw material), during the crystal growth process, the tubular core member is contacted by the growth front of the crystal and falls to the raw material, and the crystal remains non-reactive with the frame member, so that the crystal prepared by the device for preparing the silicon carbide crystal of the present disclosure has an edge with fewer defects. In addition, the frame member of the present disclosure is only a structural component, does not participate in the reaction and can be reused, and the tubular core member of high-purity graphite material is used, and the tubular core member falls off during the crystal growth process. Compared with the guide component with a fixed structure made of graphite material with a tantalum carbide or tungsten carbide coating (or plating) layer, the crystal expansion guide assembly of the present disclosure has a lower cost and does not produce impurities that affect the subsequent process. Besides, by improving the internal stress and edge stress of the crystal, the growth thickness of the crystal boule and the finished thickness of the crystal ingot are increased; the low angle grain boundary and microtubes caused by edge stress are improved, and the probability of wafer breakage during processing or manufacturing is reduced; with the same number of furnaces, furnace materials, and labor costs, the overall output of product-level wafers is increased in the present disclosure.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. A device for preparing a silicon carbide crystal, comprising:
a crucible comprising a crucible body and a crucible cover, wherein the crucible body has an internal space for accommodating a raw material, the crucible cover is configured to fix a seed and cover the crucible body; and
a crystal expansion guide assembly comprising:
a frame member fixed to the crucible body or between the crucible body and the crucible cover, located between the seed and the raw material, and provided with a through hole, wherein a diameter of the through hole is greater than a diameter of a growth surface of the seed; and
a tubular core member having flexibility and being a graphite material with a purity greater than 99.9%, wherein the tubular core member is mechanically connected to an inner wall of the through hole, an inner diameter of the tubular core member is less than or equal to the diameter of the growth surface of the seed, a length of the tubular core member is less than a distance between the tubular core member and the raw material, and during a crystal growth process, the frame member does not react with a crystal, and the tubular core member falls off to a surface of the raw material when a growth front of the crystal contacts the tubular core member.

2. The device according to claim 1, wherein an outer diameter of the tubular core member is substantially equal to the diameter of the through hole, and the tubular core member is cooperatively connected to the inner wall of the through hole.

3. The device according to claim 1, wherein the tubular core member is formed by rolling a graphite material layer with flexibility into a tubular shape, and the graphite material layer is cooperatively connected to the inner wall of the through hole.

4. The device according to claim 3, wherein the graphite material layer is graphite paper, graphite foil or a graphite blanket.

5. The device according to claim 1, wherein the tubular core member is formed by a plurality of graphite material layers with flexibility stacked together and rolled into a tube shape, top ends of the plurality of graphite material layers toward the seed are distributed in a descending step-like manner along a thickness direction of the tubular core member or in parallel, and thicknesses of the plurality of graphite material layers are the same or different.

6. The device according to claim 5, wherein when the top ends of the plurality of graphite material layers toward the seed are distributed in the descending step-like manner along the thickness direction of the tubular core member, during the crystal growth process, the growth front of the crystal sequentially contacts the plurality of graphite material layers, so that the plurality of graphite material layers that are contacted fall off to the surface of the raw material in sequence.

7. The device according to claim 5, wherein each of the plurality of graphite material layer is graphite paper, graphite foil or a graphite blanket.

8. The device according to claim 1, wherein a material of the frame member is graphite, metal carbide or a refractory compound.

9. The device according to claim 1, wherein the diameter of the through hole is substantially equal to a maximum crystal diameter.

10. A method for preparing a silicon carbide crystal, comprising the following steps:
(a) providing a system for preparing a silicon carbide crystal, which comprises a device for preparing a silicon carbide crystal, a seed and a heater, wherein the device for preparing the silicon carbide crystal comprises a crucible and a crystal expansion guide assembly, the crucible comprises a crucible body and a crucible cover, the crucible body has an internal space, the internal space is configured to accommodate a raw material, the heater is arranged around the crucible, the crucible cover is configured to fix the seed and cover the crucible body; the crystal expansion guide assembly comprises a frame member and a tubular core member; the frame member is fixed to the crucible body or between the crucible body and the crucible cover, is located between the seed and the raw material, and is provided with a through hole, the diameter of which is greater than that of a growth surface of the seed; the tubular core member is flexible and is a graphite material with a purity greater than 99.9%, the tubular core member is mechanically connected to an inner wall of the through hole, an inner diameter of the tubular core member is less than or equal to the diameter of a crystal growth surface of the seed, and a length of the tubular core member is less than a distance between the tubular core member and the raw material; and
(b) applying a growth pressure to the device for preparing the silicon carbide crystal, and applying a growth temperature to the device for preparing the silicon carbide crystal through the heater, so that a crystal grows from the seed, wherein during a crystal growth process, the frame member does not react with the crystal, and the tubular core member falls off to a surface of the raw material when a growth front of the crystal contacts the tubular core member.

11. The method according to claim 10, wherein the tubular core member is formed by rolling a graphite material layer with flexibility into a tubular shape, and the graphite material layer is cooperatively connected to the inner wall of the through hole; or the tubular core member is formed by a plurality of graphite material layers with flexibility rolled into a tubular shape, and the plurality of flexible graphite material layers are stacked in parallel and cooperatively connected to the inner wall of the through hole; step (b) comprises: during the crystal growth process, the graphite material layer/the plurality of graphite material layers falling off from the frame member to the surface of the raw material when the growth front of the crystal contacts the graphite material layer/the plurality of graphite material layers.

12. The method according to claim 11, wherein step (b) further comprises: preventing, by the graphite material layer(s) that has/have not fallen off, free carbon generated by the frame member when heated from entering the crystal.

13. The method according to claim 10, wherein the tubular core member is formed by a plurality of graphite material layers with flexibility rolled into a tubular shape, top ends of the plurality of graphite material layers toward the seed are distributed in a descending step-like manner along a thickness direction of the tubular core member and are stacked and cooperatively connected to the inner wall of the through hole; the step (b) comprises: during the crystal growth process, the plurality of graphite material layers that are contacted falling off to the surface of the raw material in sequence when the growth front of the crystal sequentially contacts the plurality of graphite material layers.

14. The method according to claim 13, wherein step (b) further comprises: preventing, by the graphite material layer(s) that has/have not fallen off, free carbon generated by the frame member when heated from entering the crystal.

15. The method according to claim 10, wherein step (b) further comprises: using a space formed between the growth front of the crystal and the frame member as a crystal expansion zone after the tubular core member falls off to the surface of the raw material, so that the crystal grows in the crystal expansion zone.

16. The method according to claim 10, wherein the crystal is selected from the group consisting of 4H silicon carbide, 6H silicon carbide and 15R silicon carbide, and the crystal comprises p-type silicon carbide, n-type silicon carbide or semi-insulating silicon carbide.

17. The method according to claim 10, wherein a diameter of the seed is greater than 6 inches, and a diameter of the crystal after expansion growth is between 145 millimeters and 205 millimeters.
